(19) United States
(12) Patent Application Publication
(10) Pub. No.: US 2025/0240961 A1
(43) Pub. Date: Jul. 24, 2025

(54) VERTICAL STRUCTURE MEMORY DEVICE

(71) Applicant: SAMSUNG ELECTRONICS CO., LTD., Suwon-si (KR)

(72) Inventors: Jinjoo PARK, Suwon-si (KR); Minhyun LEE, Suwon-si (KR); Seonghun JANG, Suwon-si (KR); Seokhoon CHOI, Suwon-si (KR)

(73) Assignee: SAMSUNG ELECTRONICS CO., LTD., Suwon-si (KR)

(21) Appl. No.: 19/022,065

(22) Filed: Jan. 15, 2025

(30) Foreign Application Priority Data
Jan. 19, 2024 (KR) 10-2024-0008928

(51) Int. Cl. H10B 43/27; H10B 43/10; H10B 43/30

(52) U.S. Cl. CPC H10B 43/27; H10B 43/10; H10B 43/30

(57) ABSTRACT

Provided is a vertical structure memory device including a substrate and a cell string on a surface of the substrate. The cell string includes a channel extending in a first direction perpendicular to the surface of the substrate, a plurality of first structure layers, each of the plurality of first structure layers having a lateral surface facing the channel, a plurality of second structure layers alternately stacked with the plurality of first structure layers in the first direction, each of the plurality of second structure layers having a protruding end that protrudes toward the channel, an insulating layer provided on the lateral surface of each of the plurality of first structure layers and the protruding end of each of the plurality of second structure layers, and a plurality of charge trap layers discontinuously provided on the insulating layer.

### CROSS-REFERENCE TO RELATED APPLICATION

This application is based on and claims priority under 35 U.S.C. § 119 to Korean Patent Application No. 10-2024-0008928, filed on Jan. 19, 2024, in the Korean Intellectual Property Office, the disclosure of which is incorporated by reference herein in its entirety.

### BACKGROUND

### 1. Field

The disclosure relates to a vertical structure memory device.

### 2. Description of the Related Art

Non-volatile memory devices include multiple memory cells that are capable of maintaining stored information even when power supply is stopped and are capable of reusing stored information when power is supplied. Non-volatile memory devices may be widely applied to mobile phones, digital cameras, and portable computer devices.

Recently, vertical NAND (V-NAND) flash memory devices have been developed as high integration and low power are required. As the integration increases, there is increasing interest in improving the charge retention of memory cells by minimizing a charge transfer between adjacent memory cells.

### SUMMARY

Provided is a vertical structure memory device including a charge trap layer that is discontinuously formed on an insulating layer.

Further, provided is a vertical structure memory device including a charge trap layer with high charge retention.

Additional aspects will be set forth in part in the description which follows and, in part, will be apparent from the description, or may be learned by practice of the presented embodiments of the disclosure.

According to an aspect of the disclosure, there is provided a vertical structure memory device including: a substrate; a cell string on a surface of the substrate, the cell string including: a channel extending in a first direction perpendicular to the surface of the substrate; a plurality of first structure layers, each of the plurality of first structure layers having a lateral surface facing the channel; a plurality of second structure layers alternately stacked with the plurality of first structure layers in the first direction, each of the plurality of second structure layers having a protruding end that protrudes toward the channel; an insulating layer provided on the lateral surface of each of the plurality of first structure layers and the protruding end of each of the plurality of second structure layers; and a plurality of charge trap layers discontinuously provided on the insulating layer.

Each of the plurality of charge trap layers may surround at least a portion of the protruding end, and at least one of the plurality of charge trap layers may be spaced apart from an adjacent charge trap layer from among the plurality of charge trap layers in the first direction.

The cell string may further include a block guide groove defined by a space between a first protruding end of a first second structure layer, among the plurality of second structure layers, and a second protruding end of a second second structure layer, among the plurality of second structure layers, and a first charge trap layer, among the plurality of charge trap layers, may be inside the block guide groove.

The block guide groove may be at a same level as a first first structure layer, among the plurality of first structure layers, in the first direction.

A first end of the first charge trap layer may be inside the block guide groove.

An end of each of the plurality of charge trap layers may be spaced apart from an end of an adjacent charge trap layer from among the plurality of charge trap layers at a certain interval.

The first charge trap layer may have a first deposition thickness in a direction perpendicular to a surface of the insulating layer, and in the first deposition thickness, a first first deposition thickness outside the block guide groove may be greater than a second first deposition thickness inside the block guide groove.

The second first deposition thickness may decrease in a direction away from the channel.

The insulating layer may have a second deposition thickness in a direction perpendicular to a surface positioned in the block guide groove from among surfaces of one of the first protruding end and the second protruding end, and the second deposition thickness may decrease in a direction away from the channel inside the block guide groove.

The cell string may further include a tunneling layer between the plurality of charge trap layers and the channel.

At least a portion of the tunneling layer may be inside the block guide groove.

A vertical thickness of a first first structure layer, among the plurality of first structure layers, may be less than a vertical thickness of a first second structure layer, among the plurality of second structure layers.

At least one of the plurality of first structure layers may include a dielectric layer, and at least one of the plurality of second structure layers may include a dielectric layer, a semiconductor layer, or a metal layer.

Each of the plurality of charge trap layers may define a memory cell.

The cell string may include a plurality of cell strings.

According to another aspect of the disclosure, there is provided an electronic device including: a vertical structure memory device including: a substrate; a cell string on a surface of the substrate, the cell string including: a channel extending in a first direction perpendicular to the surface of the substrate; a plurality of first structure layers, each of the plurality of first structure layers having a lateral surface facing the channel; a plurality of second structure layers alternately stacked with the plurality of first structure layers in the first direction, each of the plurality of second structure layers having a protruding end that protrudes toward the channel; an insulating layer provided on the lateral surface of each of the plurality of first structure layers and the protruding end of each of the plurality of second structure layers; and a plurality of charge trap layers discontinuously provided on the insulating layer.

According to another aspect of the disclosure, there is provided a method of manufacturing a vertical structure memory device including a cell string, the method including: alternately stacking a plurality of first structure layers and a plurality of second structure layers on a substrate in a first direction; forming a channel hole in the plurality of first structure layers and the plurality of second structure layers that are alternately stacked on the substrate; etching the plurality of second structure layers to be recessed in a direction away from the channel hole; depositing an insulating layer on the plurality of first structure layers and the plurality of second structure layers through the channel hole; and depositing a plurality of charge trap layers through the channel hole.

Each of the plurality of charge trap layers may be discontinuously provided on the insulating layer.

Each of the plurality of charge trap layers may be spaced apart from an adjacent charge trap layer from among the plurality of charge trap layers at a certain interval.

The depositing of the plurality of charge trap layers may include depositing a charge trap layer to be thinner in a direction toward a first second structure layer, among the plurality of second structure layers, inside a block guide groove which is a region formed in the etching of the first second structure layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a vertical structure memory device according to an embodiment;

FIG. 2 is a cross-sectional view of a vertical structure memory device according to an embodiment;

FIG. 3 is an enlarged view of a cell string according to an embodiment;

FIG. 4 is a diagram for explaining a block guide groove according to an embodiment;

FIG. 5 is a flowchart of a method of manufacturing a vertical structure memory device according to an embodiment;

FIG. 6 is a cross-sectional view showing a state in which a first structure layer and a second structure layer are alternately stacked on a substrate according to an embodiment;

FIG. 7 is a cross-sectional view showing a state in which a channel is formed in a stack structure according to an embodiment;

FIG. 8 is a cross-sectional view showing a state in which a protruding end is formed by etching a first structure layer according to an embodiment;

FIG. 9 is a cross-sectional view showing a state in which an insulating layer is deposited on a first structure layer and a second structure layer according to an embodiment;

FIG. 10 is a cross-sectional view showing a state in which a charge trap layer is deposited, according to an embodiment;

FIG. 11 is a cross-sectional view showing a state in which a first structure layer and a second structure layer are alternately stacked on a substrate according to an embodiment;

FIG. 12 is a cross-sectional view showing a state in which a protruding end is formed by etching a first structure layer according to an embodiment.

FIG. 13 is a cross-sectional view showing a state in which an insulating layer is deposited, according to an embodiment; and

FIG. 14 is a cross-sectional view showing a state in which a charge trap layer is deposited, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the attached drawings. In the following drawings, the same reference numerals refer to the same components, and the size of each component in the drawings may be exaggerated for clarity and convenience of explanation. The embodiments described below are merely illustrative, and various modifications are possible from the embodiments. Hereinafter, the term “above” or “on” may include not only those directly above, below, left, and right in contact, but also those above, below, left, and right in a non-contact manner. The singular expressions include the plural expressions unless clearly specified otherwise in context. When a certain portion “includes” a certain component, this indicates that the portion may further include another component instead of excluding another component unless there is no different disclosure. The use of the term “above” and similar terms may refer to both the singular and the plural. Unless the order of operations constituting a method is clearly stated or stated to the contrary, these operations may be performed in any appropriate order and are not necessarily limited to the order described. The terms, such as “unit” or “module” need to be understood as a unit that processes at least one function or operation and that may be embodied in a hardware manner, a software manner, or a combination of the hardware manner and the software manner. The connections or connection members of lines between components shown in the drawings may represent functional connections and/or physical or circuit connections, and in actual device, may be replaced or may represent additional various functional connections, physical connections, or circuit connections. The use of all examples or illustrative terms is simply for illustrating the technical spirit in detail, and the scope is not limited by these examples or illustrative terms unless limited by the claims.

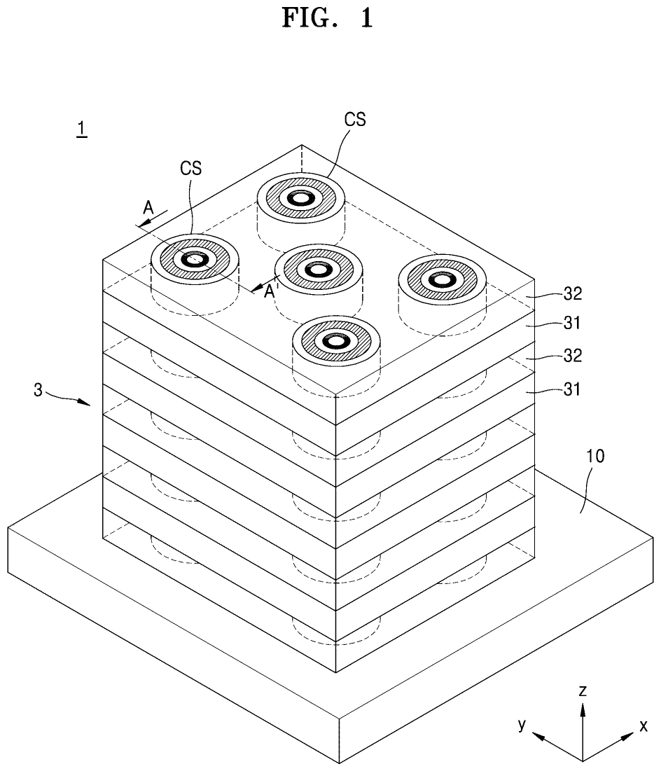

FIG. 1 is a perspective view of a vertical structure memory device 1 according to an embodiment.

Referring to FIG. 1, the vertical structure memory device 1 according to an embodiment may include a substrate 10 and a stack structure 3 provided on the substrate 10. The stack structure 3 may be provided on substrate 10. Although FIG. 1 illustrates an embodiment in which the stack structure 3 is provided directly on the substrate 10, the disclosure is not limited thereto, and as such, according to another embodiment, another layer may be provided between the stack structure 3 and the substrate 10. The stack structure 3 may include a plurality of first structure layers 31 and a plurality of second structure layers 32. The stack structure 3 may include a first structure layer 31 and a second structure layer 32 that are alternately stacked on the substrate 10.

The stack structure 3 according to an embodiment may be arranged in a direction perpendicular to the substrate 10. For example, the stack structure 3 may be arranged in a direction perpendicular to an upper surface of the substrate 10 The first structure layer 31 and the second structure layer 32 may be alternately stacked in a direction perpendicular to the substrate 10. The direction perpendicular to the substrate 10 may be an upward direction of the vertical structure memory device 1. The direction perpendicular to the substrate 10 may be a z-axis direction. However, the disclosure is not limited thereto, and as such, according to another embodiment, the direction perpendicular to the substrate 10 may be oriented in another manner.

The vertical structure memory device 1 according to an embodiment may include a cell string CS. According to an embodiment, a plurality of cell strings CS may be formed in the stack structure 3. The plurality of cell strings CS may be arranged in various shapes on the stack structure 3. The cell string CS may be formed to have a circular cross-section. However, the cross-sectional shape of the cell string CS is not limited to the above description.

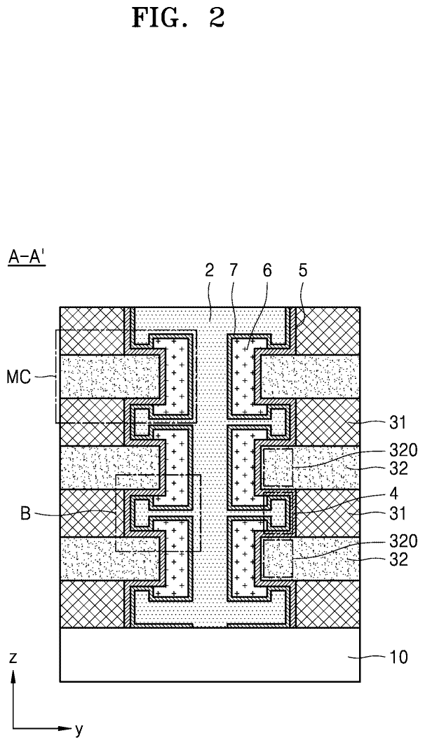

FIG. 2 is a cross-sectional view of the vertical structure memory device 1 according to an embodiment. FIG. 2 may be a portion of a cross-sectional view of the cell string CS viewed from a direction A-A′.

As shown in FIG. 2, the cell string CS may include a channel 2 formed in a direction perpendicular to the substrate 10. For example, the cell string CS may include a channel 2 formed in a direction perpendicular to an upper surface of the substrate 10. The cell string CS may be formed inside the stack structure 3. The cell string CS may be formed to pass through the stack structure 3 in a vertical direction. For example, the cell string CS may extend across multiple layers of stack structure 3. Referring to FIGS. 1 and 2, the cell string CS may include a plurality of memory cells MC stacked in a vertical direction. The memory cell MC may be a basic unit cell for storing data. For example, the memory cell MC may be capable of writing and erasing data.

The cell string CS may include the first structure layer 31 and the second structure layer 32 that are arranged to surround the channel 2. The cell string CS may include the second structure layer 32 that is alternately stacked with the first structure layer 31. The second structure layer 32 may have a protruding end 320 protruding in a direction toward the channel 2. The second structure layer 32 may include the protruding end 320 that protrudes in the direction toward the channel 2. Although some aspects of the disclosure as illustrated as the second structure layer 32 including the protruding end 320 protruding in the direction toward the channel 2, the disclosure is not limited thereto, and as such, according to another aspect of the disclosure the first structure layer 31 may be viewed as a structure in which the first structure layer 31 is recessed in a direction away from the channel 2. The protruding end 320 of the second structure layer 32 may be formed by recessing the first structure layer 31 in the direction away from the channel 2. The protruding end 320 of the second structure layer 32 may be formed by selectively etching the first structure layer 31 by an etchant flowing from an upper side of the channel 2. However, a manner in which the protruding end 320 is formed is not limited to the above description.

The first structure layer 31 according to an embodiment may be a dielectric layer. The first structure layer 31 may be a spacer. The first structure layer 31 may include, but is not limited to, silicon dioxide (SiO₂) and/or aluminum oxide (Al₂O₃).

The second structure layer 32 according to an embodiment may include at least one of a dielectric layer, a semiconductor layer, or a metal layer. The second structure layer 32 may be a dielectric layer. The second structure layer 32 may be a semiconductor layer. The second structure layer 32 may be a metal layer. The second structure layer 32 may include at least one of a sacrificial layer of a word line or a word line. The second structure layer 32 may be a word line. The second structure layer 32 may be a sacrificial layer of a word line. The second structure layer 32 may include a semiconductor, such as p-type silicon (p-Si) and/or amorphous silicon (a-Si). The second structure layer 32 may include at least one of word line metals. For example, the metal may include, but is not limited to tungsten (W), Molybdenum (Mo), Ruthenium (Ru), Aluminum (AI), Nickel (Ni), Cobalt (Co), Chromium (Cr) and Copper (Cu). The second structure layer 32 may include a mold structure to be replaced with a word line, for example, silicon nitride (SiN). However, the material and function of the second structure layer 32 are not limited to the above description.

The cell string CS according to an embodiment may include an insulating layer 5 provided on the first structure layer 31 and the second structure layer 32. The insulating layer 5 may be provided on a lateral surface of the first structure layer 31. For example, the insulating layer 5 may be provided on a side surface of each of the first structure layers 31. In this manner, the insulating layer 5 may be provided between the first structure layer 31 and the channel 2. Moreover, the insulating layer 5 may be provided on a lateral surface of the first structure layer 31, which faces the channel. The insulating layer 5 may be provided on the protruding end 320 of the second structure layer 32. The insulating layer 5 may be continuously provided on the first structure layer 31 and the second structure layer 32. The insulating layer 5 may be configured to block a charge transfer between the second structure layer 32 and a charge trap layer 6, which will be described later. The insulating layer 5 may prevent charges in the charge trap layer 6 from leaking into the second structure layer 32. The insulating layer 5 may include, but is not limited to, SiO₂ and/or Al₂O₃.

The cell string CS according to an embodiment may include the charge trap layer 6. The charge trap layer 6 may be provided on the insulating layer 5. The charge trap layer 6 may surround at least a portion of the second structure layer 32. The charge trap layer 6 may surround at least a portion of the protruding end 320. For example, the charge trap layer 6 may be provided on an upper surface, a lower surface and a side surface of the protruding end 320. According to an embodiment, the charge trap layer 6 surrounding at least a portion of the second structure layer 32 may mean that the charge trap layer 6 surrounds at least a portion of the insulating layer 5 provided on the second structure layer 32. For example, the charge trap layer 6 surrounding at least a portion of the protruding end 320 may mean that the charge trap layer 6 surrounds at least a portion of the insulating layer 5 provided on the protruding end 320. For example, the insulating layer 5 may include a first portion provided on an upper surface of the protruding end 320, a first portion provided on a lower surface of the protruding end 320 and a third portion provided on a side surface of the protruding end 320. The charge trap layer 6 may be provided on the first portion, the second portion and the third portion of the insulating layer 5. A function of the charge trap layer 6 will be described below.

The cell string CS according to an embodiment may include a tunneling layer 7 provided between the charge trap layer 6 and the channel 2. The tunneling layer 7 may be provided on the charge trap layer 6. The tunneling layer 7 may be a layer in which tunneling of charges occurs between the channel 2 and the charge trap layer 6. The tunneling layer 7 may selectively control a charge movement between the channel 2 and the charge trap layer 6. For example, the tunneling layer 7 may selectively control a charge movement between the channel 2 and the charge trap layer 6. The tunneling layer 7 may selectively control outflow of charges trapped in the charge trap layer 6. The tunneling layer 7 may include, but is not limited to, silicon oxide and/or metal oxide, for example.

The charge trap layer 6 according to an embodiment may store charges passing through the tunneling layer 7. For example, charges moving through the channel 2 may pass through the tunneling layer 7 and be trapped in the charge trap layer 6. The charge trap layer 6 may selectively trap or release charges. The charge trap layer 6 may store information by selectively trapping or releasing charges. According to an embodiment, the charge trap layer 6 traps charges may mean that information is stored in the memory cell MC. The charge trap layer 6 may form the memory cell MC. The charge trap layer 6 may form at least a portion of the memory cell MC. The charge trap layer 6 may include, but is not limited to, a semiconductor, such as nitride and/or p-Si.

The cell string CS according to an embodiment may include the plurality of charge trap layers 6. Each of the plurality of charge trap layers 6 may form a separate memory cell MC. Each of the plurality of charge trap layers 6 may form a separate body. The plurality of charge trap layers 6 may not to be in contact with each other. The plurality of charge trap layers 6 may be formed discontinuously. In an example case in which the plurality of charge trap layers 6 are formed discontinuously, the plurality of charge trap layers 6 may not be electrically connected to each other. In an example case in which the plurality of charge trap layers 6 are formed discontinuously, charges trapped in the charge trap layer 6 may be prevented from moving to an adjacent charge trap layer 6. In an example case in which the plurality of charge trap layers 6 are formed discontinuously, data retention of the memory cell MC may be excellent.

At least one of the plurality of charge trap layers 6 according to an embodiment may be formed apart from an adjacent charge trap layer 6 at a certain interval. For example, the plurality of charge trap layers 6 may be arranged apart from each other at a certain interval in a vertical direction. In an example case in which the plurality of charge trap layers 6 are formed apart from an adjacent charge trap layer 6 at a certain interval, the plurality of charge trap layers 6 may not be electrically connected to each other. In an example case in which the plurality of charge trap layers 6 are formed apart from an adjacent charge trap layer 6 at a certain interval, charges trapped in the charge trap layer 6 may be prevented from moving to the adjacent charge trap layer 6. In an example case in which the plurality of charge trap layers 6 are formed apart from an adjacent charge trap layer 6 at a certain interval, data retention of the memory cell MC may be excellent. In FIG. 2, the plurality of charge trap layers 6 are provided corresponding to each of the second structure layers 32. However, the disclosure is not limited thereto, and as such, according to another embodiment, the plurality of charge trap layers 6 may be provided at every other second structure layer 32. In another embodiment, the protruding end may be provided in the first structure layers 31 instead of the second structure layers 32. In such a case, the plurality of charge trap layers 6 may be provided corresponding to each of the first structure layers 31.

An electronic device including the vertical structure memory device 1 according to an embodiment may be provided. The electronic device including the vertical structure memory device 1 may be an electronic device with excellent data retention.

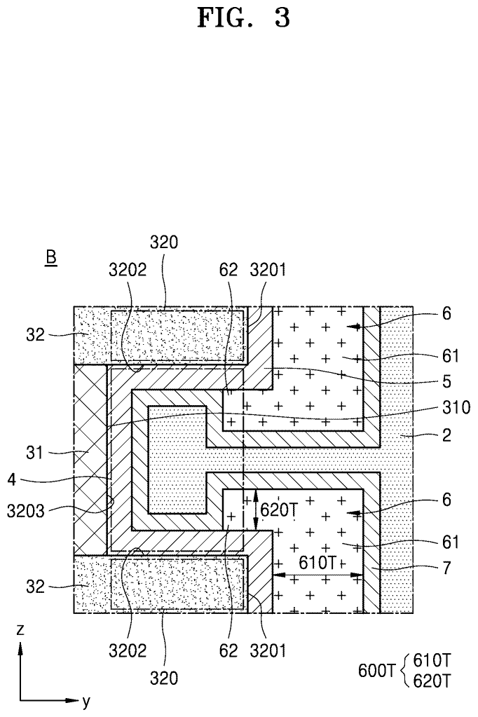

FIG. 3 is an enlarged view of the cell string CS according to an embodiment. FIG. 3 may be an enlarged view of a region B of FIG. 2.

Referring to FIGS. 2 and 3, the charge trap layer 6 according to an embodiment may include a storage portion 61 extending in a vertical direction. The storage portion 61 of the charge trap layer 6 may be a region inside the charge trap layer 6, in which charges are stored. The charge trap layer 6 may include an end 62 extending in a direction intersecting with the direction in which the storage portion 61 extends. For example, the charge trap layer 6 may include the end 62 extending in a direction intersecting with the vertical direction. The end 62 of the charge trap layer 6 may extend in a direction away from the channel 2. The ends 62 of the plurality of charge trap layers 6 may be arranged apart from the end 62 of an adjacent charge trap layer 6 at a certain interval. The tunneling layer 7 may be provided between the ends 62 of the plurality of charge trap layers 6 and the end 62 of the adjacent charge trap layer 6. However, the arrangement of the end 62 of the charge trap layer and the tunneling layer 7 is not limited to the above description.

The cell string CS according to an embodiment may include a block guide groove 4. The block guide groove 4 may be a region defined by a space between any two adjacent protruding ends 320 of the second structure layer 32. For example, a first protruding end 320 may be provided on an upper end of the block guide groove 4 and a second protruding end 320 may be provided on a lower end of the block guide groove 4. In other words, the block guide groove 4 and the protruding end 320 may be arranged side by side in the vertical direction. However, the arrangement relationship between the block guide groove 4 and the protruding end 320 is not limited to the above description.

The first structure layer 31 may be provided at a lateral side of the block guide groove 4. A recess end 310 formed by recessing the first structure layer 31 may define at least a portion of the block guide groove 4. The recess end 310 may be formed by recessing the first structure layer 31 in the direction opposite to the channel 2. The recess end 310 may define a lateral limit of the block guide groove 4 in the direction opposite to the channel 2.

The block guide groove 4 may be provided at the same level as the first structure layer 31 in a vertical direction. In other words, the block guide groove 4 and the first structure layer 31 may be arranged side by side in a horizontal direction. The first structure layer 31 may define a lateral limit of the block guide groove 4. However, the arrangement relationship between the first structure layer 31 and the block guide groove 4 is not limited to the above description.

The protruding end 320 according to an embodiment may include a first wall surface 3201 facing toward the channel 2. The first wall surface 3201 may correspond to one surface of the protruding end 320, which faces the channel 2. The first wall surface 3201 may be a portion of a region of the protruding end 320, in which the insulating layer 5 is provided.

The block guide groove 4 according to an embodiment may include a second wall surface 3202. The second wall surface 3202 may be at least a portion of a region extending in a vertical direction inside the block guide groove 4. The second wall surface 3202 may correspond to one surface of an adjacent protruding end 320, which faces the second wall surface 3202 in the vertical direction inside the block guide groove 4. The second wall surface 3202 may be a portion of a region of the protruding end 320, in which the insulating layer 5 is provided.

The block guide groove 4 according to an embodiment may include a third wall surface 3203. The third wall surface 3203 may correspond to one surface of a first structure, which faces the channel 2. The third wall surface 3203 may be a region of the first structure, in which the insulating layer 5 is provided. The third wall surface 3203 may be a region furthest from the channel 2 inside the block guide groove 4. The third wall surface 3203 may define a lateral limit of the block guide groove 4.

The second wall surface 3202 and the third wall surface 3203 may define at least a portion of the block guide groove 4. However, the above description of the second wall surface 3202 and the third wall surface 3203 is only an exemplary description and is not limited thereto.

A portion of the charge trap layer 6 according to an embodiment may be formed inside the block guide groove 4. A portion of the charge trap layer 6 may be formed inside the block guide groove 4 at a certain interval. In other words, a portion of the charge trap layer 6 provided inside the block guide groove 4 may be formed apart from an adjacent charge trap layer 6. The end 62 of the charge trap layer 6 may be formed inside the block guide groove 4. The end 62 of the charge trap layer 6 may be formed on the third wall surface 3203. A blocking layer may be provided between the end 62 of the charge trap layer 6 and the third wall surface 3203.

The end 62 of the charge trap layer 6 may not be in contact with the third wall surface 3203 inside the block guide groove 4. According to an embodiment, the end 62 of the charge trap layer 6 is not in contact with the third wall surface 3203 inside the block guide groove 4 may mean that the charge trap layer 6 is not excessively provided inside the block guide groove 4. The block guide groove 4 may prevent the charge trap layer 6 from being excessively deposited inside the block guide groove 4.

According to an embodiment, inside the block guide groove 4, the end 62 of the charge trap layer 6 may not be in contact with the end 62 of an adjacent charge trap layer. As the charge trap layer 6 is not excessively deposited inside the block guide groove 4, the end 62 of the charge trap layer 6 may not be in contact with the end 62 of the adjacent charge trap layer. The end 62 of the charge trap layer 6 may not be in contact with the first wall surface 3201 inside the block guide groove 4, and thus may not be in contact with the end 62 of the adjacent charge trap layer. However, the structure in which the end 62 of the charge trap layer 6 is provided inside the block guide groove 4 is not limited to the above description.

According to an embodiment, at least a portion of the tunneling layer 7 may be located inside the block guide groove 4. The tunneling layer 7 may be provided between the end 62 of any one charge trap layer and the end 62 of another charge trap layer inside the block guide groove 4. The tunneling layer 7 may prevent charges from moving between adjacent charge trap layers 6 inside the block guide groove 4. However, the arrangement and function of the tunneling layer 7 are not limited to the above description.

The charge trap layer 6 according to an embodiment may have a first deposition thickness 600T. The first deposition thickness 600T may be a thickness of the charge trap layer 6 is provided on the insulating layer 5. For example, the first deposition thickness 600T may be the thickness of the charge trap layer 6 deposited on the insulating layer 5. The first deposition thickness 600T may be a thickness of the insulating layer 5 in the direction perpendicular to a surface thereof. The first deposition thickness 600T may include a first first deposition thickness 610T and a second first deposition thickness 620T. The first first deposition thickness 610T may be a thickness of the charge trap layer 6 deposited on the first wall surface 3201. The first first deposition thickness 610T may be a thickness of the charge trap layer 6 toward the channel 2. The second first deposition thickness 620T may be a thickness of the charge trap layer 6 on the second wall surface 3202. The second first deposition thickness 620T may be a thickness of the charge trap layer 6 deposited in a vertical direction. The second first deposition thickness 620T may be a thickness to which the end 62 of the charge trap layer 6 is deposited. The second first deposition thickness 620T may be a thickness to which the charge trap layer 6 is deposited inside the block guide groove 4. The first first deposition thickness 610T and the second first deposition thickness 620T may be thicknesses to which the charge trap layer 6 is deposited in directions perpendicular to each other.

The charge trap layer 6 according to an embodiment may be thicker on the first wall surface 3201 than on the second wall surface 3202. The first first deposition thickness 610T of the charge trap layer 6 may be formed thicker than the second first deposition thickness 620T. The second first deposition thickness 620T may be formed thinner than the first first deposition thickness 610T. However, the relationship between the first first deposition thickness 610T and the second first deposition thickness 620T is not limited to the above description.

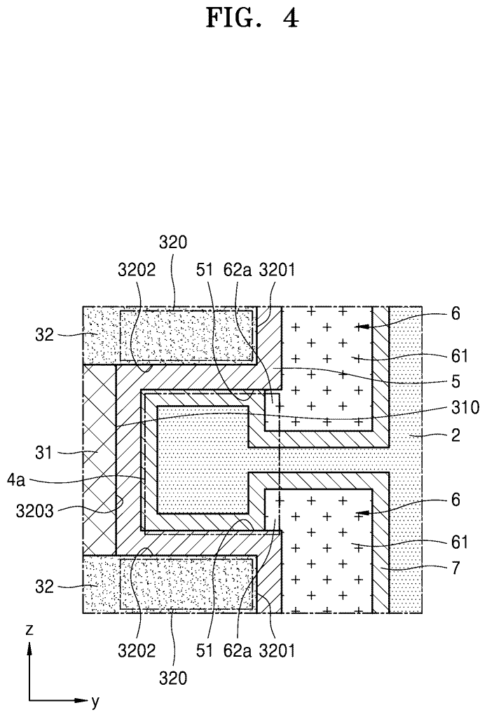

FIG. 4 is a diagram for explaining a block guide groove 4a according to an embodiment. The block guide groove 4a defined in FIG. 4 may be different from the block guide groove 4 defined in FIG. 3. FIG. 4 is a diagram to explain that the block guide groove 4 shown in FIG. 3 may be defined in various ways.

In the following, redundant descriptions will be omitted and explanations will be given in terms of differences.

Referring to FIGS. 3 and 4, the block guide groove 4a of FIG. 4 according to an embodiment may be defined differently from a blocking region of FIG. 3. The block guide groove 4a shown in FIG. 4 may be a region defined by the insulating layer 5 on the second wall surface 3202 and the third wall surface 3203. The block guide groove 4a may be defined by the insulating layer 5 on the recess end 310 of the first structure layer 31 and the protruding end 320 of the second structure layer 32. One side extending perpendicularly from a surface of the insulating layer 5 on the first wall surface 3201 may define a limit in a lateral direction of the block guide groove 4a in a direction toward the channel 2. The surface of the insulating layer 5 on the second wall surface 3202 may define a limit in a vertical direction of the block guide groove 4a. The surface of the insulating layer 5 deposited on the third wall surface 3203 may define the limit in the lateral direction of the block guide groove 4a in the direction opposite to the channel 2.

The end 62 of the charge trap layer 6 according to an embodiment may be formed inside the block guide groove 4a. The end 62 of the charge trap layer 6 may be formed at a certain distance from the end 62 of an adjacent charge trap layer inside the block guide groove 4a. The charge trap layer 6 may not be excessively deposited inside the block guide groove 4a. According to an embodiment, the charge trap layer 6 is not excessively deposited inside the block guide groove 4a may mean that the end 62 of the charge trap layer 6 is not in contact with the insulating layer 5 provided on the third wall surface 3203. The end 62 of the charge trap layer 6 may not be in contact with the insulating layer 5 provided on the third wall surface 3203 inside the block guide groove 4a, and thus may not be in contact with the end 62 of the adjacent charge trap layer. However, a method in which the end 62 of the charge trap layer 6 is provided inside the block guide groove 4a is not limited to the above description.

The block guide groove 4a formed by the first structure layer 31 and the second structure layer 32 may have various forms in addition to the block guide groove 4a described with reference to FIG. 3 and the block guide groove 4a described with reference to FIG. 4 as long as the end 62 of the charge trap layer 6 is blocked from being connected to the end 62 of the adjacent charge trap layer.

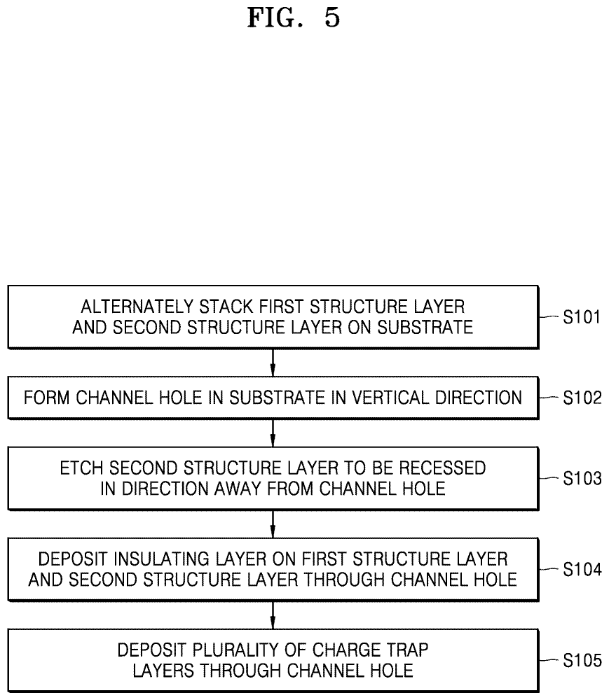

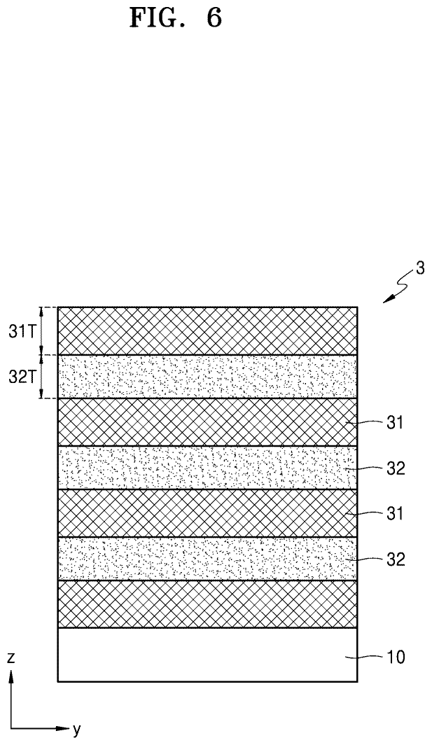

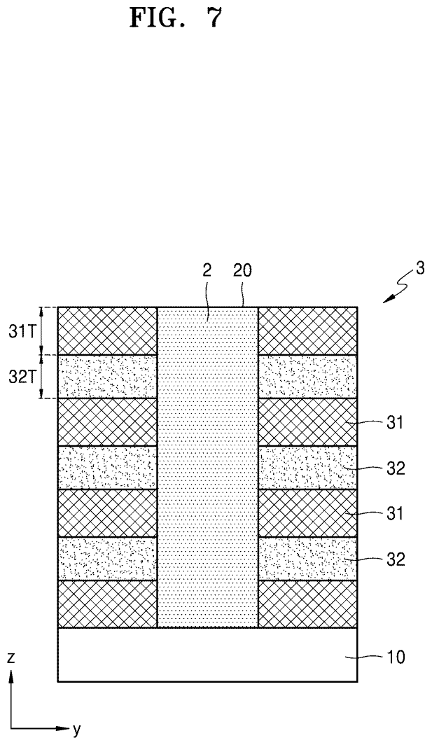

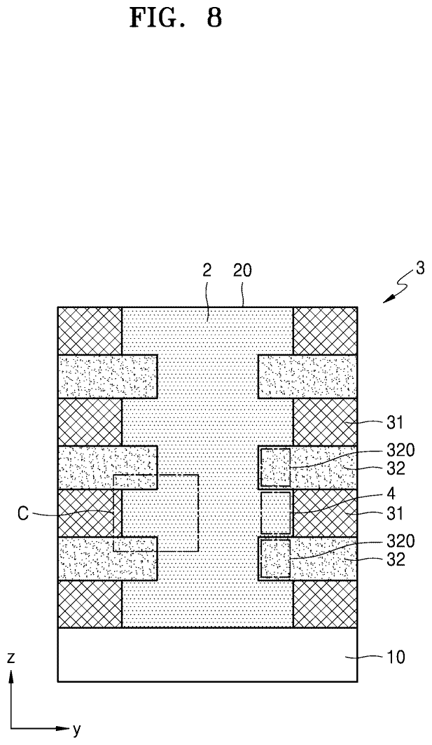

FIG. 5 is a flowchart of a method of manufacturing the vertical structure memory device 1 according to an embodiment. FIG. 6 is a cross-sectional view showing a state in which the first structure layer 31 and the second structure layer 32 are alternately stacked on the substrate 10 according to an embodiment. FIG. 7 is a cross-sectional view showing a state in which the channel 2 is formed in the stack structure 3 according to an embodiment. FIG. 8 is a cross-sectional view showing a state in which the protruding end 320 is formed by etching the first structure layer 31 according to an embodiment.

Referring to FIGS. 1 and 5 to 8, the method of manufacturing the vertical structure memory device 1 according to an embodiment may be a method of manufacturing the vertical structure memory device 1 including the cell string CS. The method of manufacturing the vertical structure memory device 1 may be a method of manufacturing the vertical structure memory device 1 including the plurality of cell strings CS.

In operation S101, the method of manufacturing the vertical structure memory device 1 according to an embodiment may include alternately stacking the first structure layer 31 and the second structure layer 32 on the substrate 10. The operation S101 of alternately stacking the first structure layer 31 and the second structure layer 32 on the substrate 10 may include alternately stacking the first structure layer 31 and the second structure layer 32 on the substrate 10 in a direction perpendicular to an upper surface of the substrate. The first structure layer 31 and the second structure layer 32 may form the stack structure 3 on the substrate 10. According to an embodiment, the first structure layer 31 may have a first thickness 31T and the second structure layer 32 may have a second thickness 32T. The first thickness 31T and the second thickness 32T may be same or different from each other. In FIGS. 6-8, the first thickness 31T and the second thickness 32T are same.

In operation S102, the method of manufacturing the vertical structure memory device 1 according to an embodiment may include forming a channel hole in the first structure layer and the second structure layer that are alternately stacked on the substrate 10 in the direction perpendicular to the upper surface of the substrate. The operation S102 of forming the channel hole in the first structure layer and the second structure layer that are alternately stacked on the substrate 10 in the direction perpendicular to the upper surface of the substrate may include forming the channel hole through the stack structure 3 from the top to the bottom in the direction perpendicular to the substrate 10. A channel hole 20 may be an entrance of the channel 2, and may be provided at an upper side of the stack structure 3. There may be a plurality of channel holes 20 formed in a direction perpendicular to the substrate 10. The channel hole 20 formed in the direction perpendicular to the substrate 10 may correspond to the cell string CS.

In operation S103, the method of manufacturing the vertical structure memory device 1 according to an embodiment may include etching the second structure layer 32 to recess the second structure layer 32 in a direction away from the channel hole 20. The operation S103 of etching the second structure layer 32 in the direction away from the channel hole 20 may include providing an etchant in a direction toward the channel hole 20. The etchant provided in a direction from the channel hole 20 may selectively etch the second structure layer 32. The protruding end 320 may be formed on the first structure layer 31 through operation S103 of etching the second structure layer 32 to recess the second structure layer 32 in the direction away from the channel hole 20. The protruding end 320 of the first structure layer 31 may be formed such that the second structure layer 32 is recessed in the direction away from the channel hole 20.

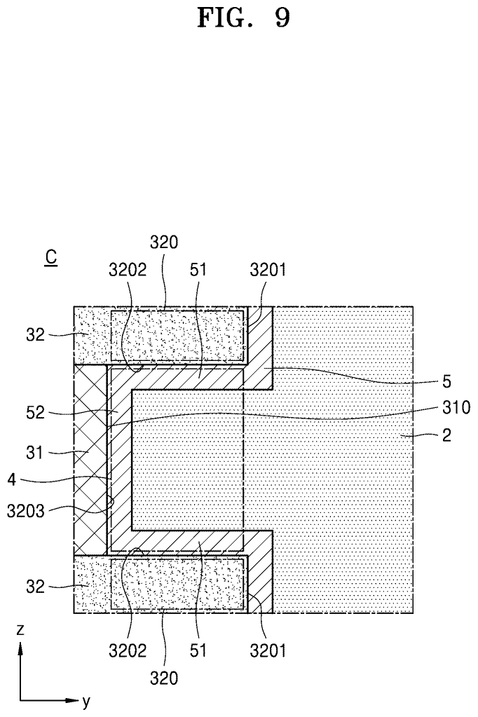

FIG. 9 is a cross-sectional view showing a state in which the insulating layer 5 is deposited on the first structure layer 31 and the second structure layer 32 according to an embodiment. FIG. 9 may be an enlarged view of a region C of FIG. 8 after the insulating layer 5 is deposited on the first structure layer 31 and the second structure layer 32 of FIG. 8.

Referring to FIGS. 1 and 5 to 9, in operation S104, the method of manufacturing the vertical structure memory device 1 according to an embodiment may include depositing the insulating layer on the first structure layer 31 and the second structure layer 32 through the channel hole 20. The insulating layer 5 may be deposited on the first structure layer 31 and the second structure layer 32. The insulating layer 5 may be deposited on the first wall surface 3201, the second wall surface 3202, and the third wall surface 3203.

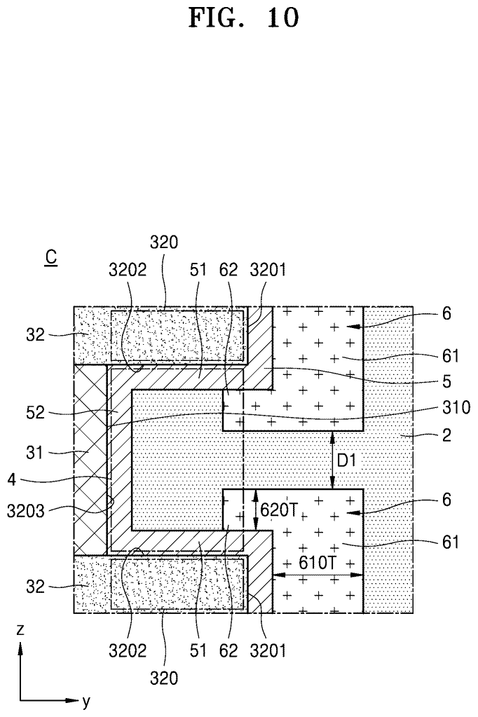

FIG. 10 is a cross-sectional view showing a state in which the charge trap layer 6 is deposited, according to an embodiment.

Referring to FIGS. 5 to 10, in operation S105, the method of manufacturing the vertical structure memory device 1 according to an embodiment may include depositing the plurality of charge trap layers 6 through the channel hole 20. The operation S105 of depositing the plurality of charge trap layers 6 through the channel hole 20 may include depositing the charge trap layer 6 on each of the plurality of protruding ends 320. The operation S105 of depositing the plurality of charge trap layers 6 through the channel hole 20 may include depositing the plurality of charge trap layers 6 on the insulating layer 5. Operation S105 of depositing the plurality of charge trap layers 6 through the channel hole 20 may include discontinuously forming each of the plurality of charge trap layers 6 such that no charge trap layer 6 is in contact with an adjacent charge trap layer 6. Operation S105 of depositing the plurality of charge trap layers 6 through the channel hole 20 may include depositing the charge trap layers such that the plurality of charge trap layers 6 are formed apart from each other at a certain distance D1 (S105).

In operation S105 of depositing the plurality of charge trap layers 6 through the channel hole 20, the charge trap layer 6 may be deposited on the first wall surface 3201. The charge trap layer 6 may be deposited on at least a portion of the second wall surface 3202. The charge trap layer 6 may be deposited with an end thereof provided on the second wall surface 3202. The charge trap layer 6 may be deposited with an end thereof formed inside block guide groove 4. The first first deposition thickness 610T of the charge trap layer 6 may be deposited thicker than the second first deposition thickness 620T. The second first deposition thickness 620T of the charge trap layer 6 may be deposited thinner than the first first deposition thickness 610T. The first first deposition thickness 610T may be about 0.3 nm to about 1.5 nm, but is not limited thereto.

According to an embodiment, the charge trap layer 6 is deposited on the first wall surface 3201 and the second wall surface 3202 may mean the charge trap layer 6 is deposited on the insulating layer 5 deposited on the first wall surface 3201 and the second wall surface 3202. The insulating layer 5 may be provided between the charge trap layer 6 and the first wall surface 3201. The insulating layer 5 may be provided between the charge trap layer 6 and the second wall surface 3202.

In this case, the insulating layer 5 deposited on the second wall surface 3202 may be referred to as an insulating layer lateral wall 51. The insulating layer 5 deposited on the third wall surface 3203 may be referred to as an insulating layer internal wall 52.

In operation S105 of depositing the plurality of charge trap layers 6 through the channel hole 20, the charge trap layer 6 may not be excessively deposited inside the block guide groove 4. As the charge trap layer 6 is not excessively deposited inside the block guide groove 4, no charge trap layer 6 may be in contact with another adjacent charge trap layer 6. The charge trap layer 6 may not be deposited on the third wall surface 3203. The charge trap layer 6 may not be deposited on the insulating layer internal wall 52. As the charge trap layer 6 is not deposited on the third wall surface 3203, no charge trap layer 6 may be in contact with another adjacent charge trap layer 6. As the charge trap layer 6 is not deposited on the insulating layer internal wall 52, no charge trap layer 6 may be in contact with another adjacent charge trap layer 6. The block guide groove 4 may prevent the charge trap layer 6 from being deposited on the third wall surface 3203. The block guide groove 4 may prevent the charge trap layer 6 from being deposited on the insulating layer internal wall 52. However, a method of depositing the charge trap layer 6 inside the block guide groove 4 is not limited to the above description.

The charge trap layer 6 according to an embodiment may be deposited through an atomic layer deposition (ALD) process. According to an embodiment, a precursor configured to be bonded to the insulating layer 5 may be used in a case in which the charge trap layer 6 is deposited through an ALD process. The precursor may move through the channel hole 20 and be bonded to the insulating layer 5. The precursor may be chemically bonded to the insulating layer 5. The precursor may include a reactor having chemical reactivity with the insulating layer 5 and a ligand having an unshared electron pair. The reactor contained in the precursor may be chemically bonded to the insulating layer 5. The ligand contained in the precursor may not have chemical reactivity with the precursor. The ligand contained in the precursor may constitute at least a portion of a three-dimensional structure formed by the precursor. The ligand of the precursor may not overlap ligands of adjacent precursors.

The insulating layer 5 deposited on the second wall surface 3202 and the third wall surface 3203 may be one body. In other words, the insulating layer internal wall 52 and the insulating layer lateral wall 51 may be one body. The insulating layer internal wall 52 and the insulating layer lateral wall 51 may have a continuous structure. In an example case in which the charge trap layer 6 is deposited on the insulating layer 5, the insulating layer internal wall 52 and the insulating layer lateral wall 51 may have the same chemical composition. In an example case in which the insulating layer internal wall 52 and the insulating layer lateral wall 51 may have the same chemical composition, it may be necessary to restrict a movement path of the precursor to prevent the precursor of the charge trap layer 6 from reaching the insulating layer internal wall 52 to selectively deposit the charge trap layer 6 on the insulating layer lateral wall 51.

In an example case in which the charge trap layer 6 according to an embodiment is deposited through an ALD process, a precursor having a large ligand may be used. In an example case in which a precursor with a large ligand moves through the channel hole 20, a degree of freedom of movement may not be large due to interference between other precursors. The degree of freedom of movement by which the precursor is moveable through the channel hole 20 may include a concept of a mean free path. A precursor with a large ligand may not have a long mean free path. However, movement of the precursor with a large ligand is not limited to the above description.

In an example case in which the charge trap layer 6 according to an embodiment is deposited through an ALD process, if a precursor with a large ligand is used, it may not be easy for the precursor to enter the block guide groove 4. In an example case in which a precursor with a large ligand is used during deposition of the charge trap layer 6 through an ALD process, the amount of the charge trap layer 6 deposited inside the block guide groove 4 may not be large. In an example case in which a precursor with a large ligand is used during deposition of the charge trap layer 6 through an ALD process, even if the insulating layer internal wall 52 and the insulating layer lateral wall 51 have the same chemical composition, the charge trap layer 6 may be selectively deposited on the insulating layer lateral wall 51. As the charge trap layer 6 is not deposited on the insulating layer internal wall 52 inside the block guide groove 4, no charge trap layer 6 may be in contact with an adjacent charge trap layer 6. In an example case in which a precursor with a large ligand is used during deposition of the charge trap layer 6 through an ALD process, the end 62 of the charge trap layer 6 may not be in contact with the end 62 of the adjacent charge trap layer inside the block guide groove 4.

Referring back to FIG. 10, a certain distance D1 may be present between the charge trap layer 6 and the adjacent charge trap layer 6 according to an embodiment. In an example case in which the charge trap layer 6 is deposited on the insulating layer 5, the distance D1 with the charge trap layer 6 may decrease. In operation S105 of depositing the plurality of charge trap layers 6 through the channel hole 20, the charge trap layer 6 may be deposited on the insulating layer 5. In an example case in which the charge trap layer 6 is deposited on the insulating layer 5, the first first deposition thickness 610T and the second first deposition thickness 620T may be increased. As the first first deposition thickness 610T and the second first deposition thickness 620T are increased, the distance D1 with the charge trap layer 6 may decrease. In Operation S105 of depositing the plurality of charge trap layers 6 through the channel hole 20, it may be difficult for a precursor with a large ligand to enter the inside of the block guide groove 4 through the distance D1 with the charge trap layer 6. The charge trap layer 6 may be prevented from being deposited on the insulating layer internal wall 52 by restricting the precursor from entering the inside of the block guide groove 4 through the distance with the charge trap layer 6.

The distance D1 with the charge trap layer 6 may be controlled by applying different thicknesses to the first structure layer 31 and the second structure layer 32. Hereinafter, the stack structure 3 in which the first structure layer 31 and the second structure layer 32 have different thicknesses will be described. In this case, redundant descriptions of the above description will be omitted and explanations will be given in terms of differences.

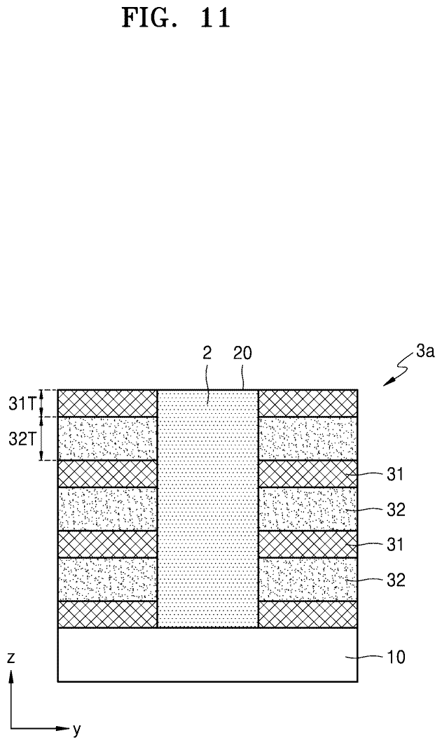

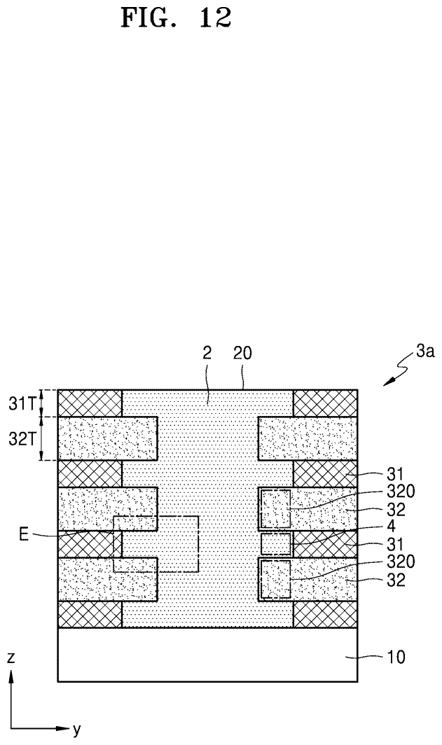

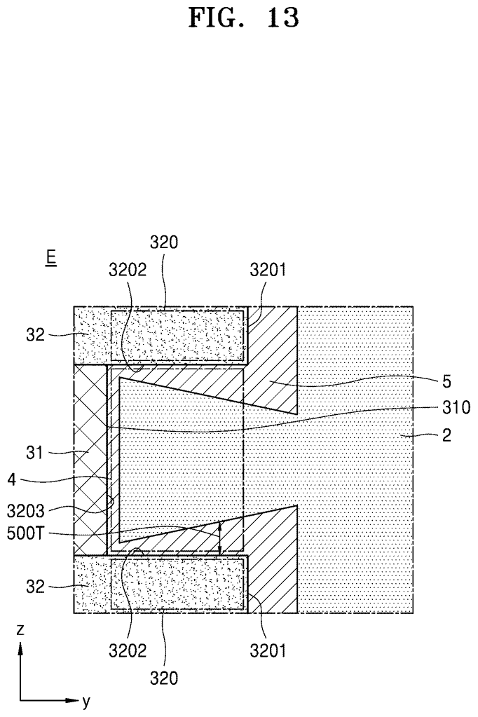

FIG. 11 is a cross-sectional view showing a state in which the first structure layer 31 and the second structure layer 32 are alternately stacked on the substrate 10 according to an embodiment. FIG. 12 is a cross-sectional view showing a state in which the protruding end 320 is formed by etching the first structure layer 31 according to an embodiment. FIG. 13 is a cross-sectional view showing a state in which the insulating layer 5 is deposited, according to an embodiment. FIG. 13 may be an enlarged view of a region E of FIG. 12 after the insulating layer 5 is deposited on the first structure layer 31 and the second structure layer 32 of FIG. 12.

Referring to FIGS. 11 to 13, a stack structure 3a according to an embodiment may include the first structure layer 31 and the second structure layer 32 that have different thicknesses. A vertical thickness (e.g., first thickness 31T) of the first structure layer 31 may be different from a vertical thickness (e.g., the second thickness 32T) of the second structure layer 32. The vertical thickness of the first structure layer 31 may be less than the vertical thickness of the second structure layer 32. The vertical thickness of the second structure layer 32 may be greater than the vertical thickness of the first structure layer 31.

The insulating layer 5 according to an embodiment may be deposited on the first structure layer 31 and the second structure layer 32. The insulating layer 5 may have a second deposition thickness 500T. The second deposition thickness 500T of the insulating layer 5 may be defined as a thickness in a direction perpendicular to a surface positioned in the block guide groove 4 from among surfaces of the protruding end 320. The second deposition thickness 500T of the insulating layer 5 may be defined as a thickness by which the insulating layer 5 is deposited on the second wall surface 3202. However, the thicknesses of the first structure layer 31 and the second structure layer 32 are merely illustrative and are not limited to the above description.

The second deposition thickness 500T according to an embodiment may be formed non-uniformly. The second deposition thickness 500T may be formed to decrease in a direction away from the channel 2 inside the block guide groove 4. According to an embodiment, the second deposition thickness 500T is formed to decrease away from the channel 2 inside the block guide groove 4 may mean that a deposition condition is intentionally adjusted to have poor step coverage. According to an embodiment, the second deposition thickness 500T is formed to decrease away from the channel 2 inside the block guide groove 4 may mean poor step coverage due to the vertical thickness of the first structure layer 31 being less than the vertical thickness of the second structure layer 32. However, the structure of the second deposition thickness 500T is not limited to the above description.

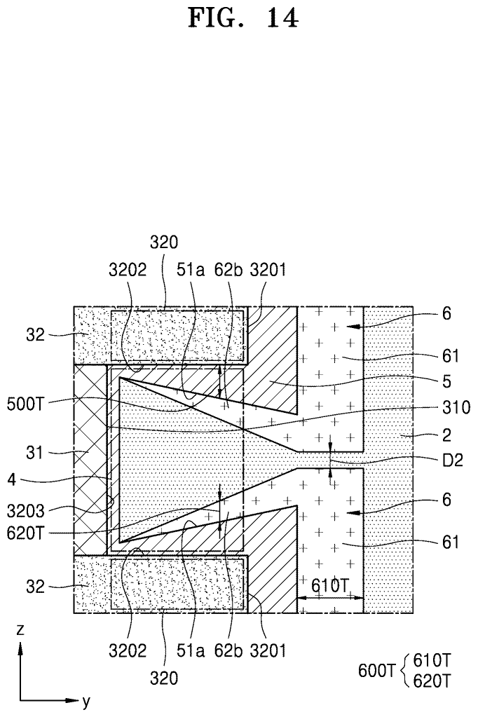

FIG. 14 is a cross-sectional view showing a state in which the charge trap layer 6 is deposited, according to an embodiment.

Referring to FIGS. 10, 13, and 14, the charge trap layer 6 according to an embodiment may be deposited on the insulating layer 5. A certain distance D2 may be present between the charge trap layer 6 and the adjacent charge trap layer 6. In an example case in which the second deposition thickness 500T of the insulating layer 5 is formed non-uniformly, the distance D1 with the charge trap layer 6 may be small. In an example case in which the step coverage of the insulating layer 5 is poor, the distance D2 with the charge trap layer 6 may be small. In an example case in which the distance D2 with the charge trap layer 6 is small, the precursor of the charge trap layer 6 may be blocked from entering the inside of the block guide groove 4. In an example case in which the distance D2 with the charge trap layer 6 is small, it may be difficult for the charge trap layer 6 to be deposited inside the block guide groove 4. In an example case in which the distance D2 with the charge trap layer 6 is small, the charge trap layer 6 may be prevented from being in contact with the adjacent charge trap layer 6.

The charge trap layer 6 according to an embodiment may have the second first deposition thickness 620T on the insulating layer lateral wall 51. The second first deposition thickness 620T may be formed to decrease away from the channel 2. In an example case in which the second first deposition thickness 620T is formed to decrease away from the channel 2, the charge trap layer 6 may be prevented from being deposited on the third wall surface 3203.

The above-described embodiments are merely illustrative, and various modifications and other equivalent embodiments may be made by those skilled in the art. Therefore, the true scope according to an embodiment should be determined by the technical spirit described in the following claims.

In the vertical structure memory device according to an embodiment, a charge trap layer structure in which charge trap layers are selectively deposited on an insulating layer and arranged apart from each other may be provided.

In the vertical structure memory device according to an embodiment, a charge trap layer may be prevented from being excessively deposited inside a block guide groove and being connected to an adjacent charge trap layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical structure memory device comprising:
a substrate;
a cell string on a surface of the substrate, the cell string comprising:
a channel extending in a first direction perpendicular to the surface of the substrate;
a plurality of first structure layers, each of the plurality of first structure layers having a lateral surface facing the channel;
a plurality of second structure layers alternately stacked with the plurality of first structure layers in the first direction, each of the plurality of second structure layers having a protruding end that protrudes toward the channel;
an insulating layer provided on the lateral surface of each of the plurality of first structure layers and the protruding end of each of the plurality of second structure layers; and
a plurality of charge trap layers discontinuously provided on the insulating layer.

2. The vertical structure memory device of claim 1, wherein each of the plurality of charge trap layers surround at least a portion of the protruding end, and
wherein at least one of the plurality of charge trap layers is spaced apart from an adjacent charge trap layer from among the plurality of charge trap layers in the first direction.

3. The vertical structure memory device of claim 2, wherein the cell string further comprises a block guide groove defined by a space between a first protruding end of a first second structure layer, among the plurality of second structure layers, and a second protruding end of a second second structure layer, among the plurality of second structure layers, and
wherein a first charge trap layer, among the plurality of charge trap layers, is inside the block guide groove.

4. The vertical structure memory device of claim 3, wherein the block guide groove is at a same level as a first first structure layer, among the plurality of first structure layers, in the first direction.

5. The vertical structure memory device of claim 4, wherein a first end of the first charge trap layer is inside the block guide groove.

6. The vertical structure memory device of claim 1, wherein an end of each of the plurality of charge trap layers is spaced apart from an end of an adjacent charge trap layer from among the plurality of charge trap layers at a certain interval.

7. The vertical structure memory device of claim 3, wherein the first charge trap layer has a first deposition thickness in a direction perpendicular to a surface of the insulating layer, and wherein, in the first deposition thickness, a first first deposition thickness outside the block guide groove is greater than a second first deposition thickness inside the block guide groove.

8. The vertical structure memory device of claim 7, wherein the second first deposition thickness decreases in a direction away from the channel.

9. The vertical structure memory device of claim 8, wherein the insulating layer has a second deposition thickness in a direction perpendicular to a surface positioned in the block guide groove from among surfaces of one of the first protruding end and the second protruding end, and
wherein the second deposition thickness decreases in a direction away from the channel inside the block guide groove.

10. The vertical structure memory device of claim 9, wherein the cell string further comprises a tunneling layer between the plurality of charge trap layers and the channel.

11. The vertical structure memory device of claim 10, wherein at least a portion of the tunneling layer is inside the block guide groove.

12. The vertical structure memory device of claim 1, wherein a vertical thickness of a first first structure layer, among the plurality of first structure layers, is less than a vertical thickness of a first second structure layer, among the plurality of second structure layers.

13. The vertical structure memory device of claim 1, wherein at least one of the plurality of first structure layers comprises a dielectric layer, and
at least one of the plurality of second structure layers comprises a dielectric layer, a semiconductor layer, or a metal layer.

14. The vertical structure memory device of claim 1, wherein each of the plurality of charge trap layers defines a memory cell.

15. The vertical structure memory device of claim 1, wherein the cell string comprises a plurality of cell strings.

16. An electronic device comprising:
a vertical structure memory device comprising:
a substrate;
a cell string on a surface of the substrate, the cell string comprising:
a channel extending in a first direction perpendicular to the surface of the substrate;
a plurality of first structure layers, each of the plurality of first structure layers having a lateral surface facing the channel;
a plurality of second structure layers alternately stacked with the plurality of first structure layers in the first direction, each of the plurality of second structure layers having a protruding end that protrudes toward the channel;
an insulating layer provided on the lateral surface of each of the plurality of first structure layers and the protruding end of each of the plurality of second structure layers; and
a plurality of charge trap layers discontinuously provided on the insulating layer.

17. A method of manufacturing a vertical structure memory device including a cell string, the method comprising:
alternately stacking a plurality of first structure layers and a plurality of second structure layers on a substrate in a first direction;
forming a channel hole in the plurality of first structure layers and the plurality of second structure layers that are alternately stacked on the substrate;
etching the plurality of second structure layers to be recessed in a direction away from the channel hole;
depositing an insulating layer on the plurality of first structure layers and the plurality of second structure layers through the channel hole; and
depositing a plurality of charge trap layers through the channel hole.

18. The method of claim 17, wherein each of the plurality of charge trap layers is discontinuously provided on the insulating layer.

19. The method of claim 18, wherein each of the plurality of charge trap layers is spaced apart from an adjacent charge trap layer from among the plurality of charge trap layers at a certain interval.

20. The method of claim 19, wherein the depositing of the plurality of charge trap layers comprises depositing a charge trap layer to be thinner in a direction toward a first second structure layer, among the plurality of second structure layers, inside a block guide groove which is a region formed in the etching of the first second structure layer.
